(19) United States
(12) Patent Application Publication
(10) Pub. No.: US 2017/0334114 A1
(43) Pub. Date: Nov. 23, 2017

(54) METHOD AND DEVICE FOR POTTING AN LED LUMINAIRE POTTED IN A POTTING COMPOUND, AND LED LUMINAIRE

(71) Applicant: GEOMAR Helmholtz-Zentrum für Ozeanforschung Kiel, Kiel (DE)

(72) Inventors: Jan STICKLUS, Eckernfoerde (DE); Tom KWASNITSCHKA, Kiel (DE); Peter Adam HOEHER, Heikendorf (DE)

(21) Appl. No.: 15/533,130

(22) PCT Filed: Dec. 9, 2015
(86) PCT No.: PCT/DE2015/100529

§ 371 Date: Jun. 5, 2017

(30) Foreign Application Priority Data
Dec. 15, 2014 (DE) 10 2014 118 671.0
Dec. 15, 2014 (DE) 10 2014 118 672.9

(51) Int. Cl. B29C 45/76; B29C 45/14; F21V 31/04; H05K 1/18; H05K 3/28; H05K 1/02; F21K 99/90; F21Y 2115/10

(52) U.S. Cl. CPC B29C 45/768; H05K 1/0274; B29C 45/14639; F21K 9/90; F21V 31/04; H05K 1/181; H05K 3/284; B29C 2945/76568; B29C 2945/76498; F21Y 2115/10; B29C 2945/76287; B29C 2945/76153; H05K 2203/163; H05K 2201/10106; H05K 2201/10287; H05K 2201/10522; H05K 2203/1316; H05K 2203/1327; B29C 2945/76795

(57) ABSTRACT

An LED luminaire and potting method having the following steps: introducing a configured luminaire into an at least partly optically transparent potting mold (16), such that the luminaire does not come into contact with the walls of the potting mold; introducing an optically transparent potting compound (18) into the potting mold (16) until at least the luminaire is surrounded; and detecting a quantity of bubbles by an optical sensor or image detector (14), wherein the pressure in the vacuum chamber (11) is controlled in order to influence the bubbles and/or a pivot/inclination device (12) is controlled in order to move the vacuum chamber (11) and/or the potting mold (16) in order to expel detected gas/air bubbles (19) out of the optically transparent potting compound (18).

The invention relates to an LED luminaire potting method, comprising the following steps: introducing a configured luminaire to be potted with an optically transparent potting compound into an at least partially optically transparent potting mold, the potting mold being arranged in a vacuum chamber and the luminaire in the potting mold being fixed in such a way that the luminaire does not contact the walls of the potting mold; introducing an optically transparent potting compound into the potting mold until at least the luminaire is enclosed; detection of a quantity of bubbles and the quality of the bubble-freeness of the optically transparent potting compound by means of an optical sensor or image detector.

Furthermore, the invention relates to an LED luminaire with at least one LED, at least one supply line which electrically contacts the LED and supplies energy, the LED being arranged in a potting compound and being produced, in particular, by an LED luminaire potting method according to one of the preceding claims, and an LED-potting luminaire manufacturing device.

One of the main problems encountered in optical inspection and mapping tasks in the deep sea or in offshore construction areas is the compressive strength of luminaires with sufficient illumination for the areas to be examined.

The production of luminaires, in which essential components of the luminaire are encapsulated without bubbles, and so lead not only to ensuring the stability of the mounting of the components, but also to the reduction of number of components, simplification of production, improvement of change-out, maintenance and service work, and reliability, and further advantages, attributable among other things to modularity, is desired for many reasons.

The requirements for illuminants that are used under water, at high pressure and great depths, are complex. In addition to high energy efficiency, much emphasis is placed on a low maintenance, compact, simple design with preferably relatively small geometry and low-cost manufacturing. Particularly in the case of use on autonomous underwater vehicles (AUVs), a high light output and as small, lightweight design plays an important role.

In classical methods for the production of light sources suitable for use in the deep sea, known suitable luminaires are accommodated in elaborately produced dedicated pressure housings, which are large, heavy and complex, and which also present difficulties in the heat dissipation of the luminaires.

For the respective applications as flash light, stroboscope light or continuous light, different luminaires are known with their own requirement-dependent housing geometries, such as shown, for example, by Kongsberg Maritime Ltd. in their company brochure, “UT2 the magazine of the society for underwater technology, Shining a Light on LEDs (Article Reprint)”, January 2010, online: http://www.km.kongsberg.com/ks/web/nokbg0397.nsf/AllWeb/06F29EA95A55158CC1257704004A2B26/$file/shininglight_viewable.pdf.

In addition to known xenon and mercury vapor luminaires, LED luminaires are increasingly being mounted in pressure housings, as shown there.

DE 20 2008 012 002 U1 shows a LED luminaire with polyurethane resin (PU) potting for use on offshore wind energy systems with a U-shaped housing and LEDs on a printed circuit board. The LED luminaire is made resistant to weathering by the potting and offers a good adherence to the surrounding walls in which the LED luminaire is embedded.

DE 10 2012 201 447 A1 shows an LED with a very thin protective layer of 1 to 100 μm, which is intended to protect the LED mounted on a printed circuit board against environmental influences without substantially changing the optical properties.

DE 10 2011 106 252 A1 shows a multi-part structure of a luminaire with a prefabricated luminaire body with transparent section which forms a light exit surface of the housing and a luminaire support as a circuit board with contacts and cavities which is potted with a potting compound and thus is suitable for use in damp rooms, cooling rooms or explosive danger rooms.

DE 10 2008 009 808 A1 shows an LED light strip with contoured potting compound as a lens replacement. The LED is mounted on a circuit board which is supported on a carrier material made of metal, plastic or wood. The potting compound offers moisture protection, impact protection, scratch protection or corrosion protection. The carrier material protrudes from the potting compound.

US 2004/0200122 A1 shows an illuminated artificial fishing lure with LEDs, electronics and batteries accommodated in a housing, which is suitable for sea fishing of tuna fish which are caught at a depth of up to 80 m.

JP 2008 053 545 A shows an LED on a carrier substrate in which, by heating and melting a glass powder, the LED is encapsulated between the carrier substrate and molten glass powder.

US 2009/0154156 A1 shows one or more LEDs mounted on a substrate of insulating material with conductive connections and reflectors enclosed by an optically transmissive or semipermeable material, such as plastic or an elastomer.

EP 2 505 906 A2 shows a method for producing an LED-based lighting body as a luminescent replacement for a fluorescent tube. In this case, a carrier strip equipped with several LEDs with conductor tracks and further electronic components is embedded in a theimoplastic by way of plastic extrusion.

US 2004/0218389 A1 shows an LED luminaire for use on boat trailers/boats with LEDs arranged on a printed circuit board which are enclosed by a biopolymer to become water repellent or waterproof or shock resistant.

Potting process for pressure-neutrally built LED luminaires, which are carried out as a so-called vacuum casting in a vacuum chamber, are known, among other things, from the joint project “Pressure-neutral systems” (DNS) in which German institutes and companies are involved (brochure: Maritime Success Stories, Research for Shipping and Marine Technology, PTJ Project Management Jülich, December 2012, pp. 43 to 45, FKZ: DNS 03SX220/03SX276, http://foerderportal.bund.de/foekat).

For such applications, it is important to carry out the potting in a vacuum. This applies in particular to several components that are to be cast jointly and have strong undercuts or in a very confined space.

Small air bubbles may be enclosed in the potting material, as well as in small cavities, for example in wire windings. These can, inter alia, jeopardize the high-voltage resistance or cause corrosion, to the extent that they also introduce moisture. In order to ensure without exception a bubble-freeness, the entire processing, conveying and dosing process must therefore be carried out under vacuum.

The vacuum process is also a suitable process when moisture-sensitive casting resins are used. The processing under vacuum is intended to exclude undesired secondary reactions of the potting medium or the incorporation of air.

If a vacuum is mentioned in the production process, a pressure reduction down to one millibar is generally meant. When potting electronic components, a real vacuum, i.e., complete air evacuation, is not necessary.

The further the air pressure is lowered, the longer the evacuation takes and the greater the energy costs and the time required. For this reason, in the prior art, the vacuum is specifically adapted to the respective task.

Not to be overlooked is that not every component can withstand a strong pressure reduction. While a winding material is largely insensitive, the encapsulated air in a condenser can cause the condenser to burst, in the case of an external relative vacuum of between 2 and 50 millibar. This means that, in the case of potting with lower pressures, air traces can still be present such a component, which are enclosed by the potting compound.

The company Enitech (Rostock), which was involved in the pressure-neutral systems (DNS) deep-sea project “Deep water, design, implementation and testing of pressure-neutral systems and equipment for long-term underwater operation in vehicles and underwater structures”, concluded that “ . . . the simple potting of an assembly in a plastic housing with an embedding grout and a final skin grout as a membrane is not suitable and failed after some immersion tests with most assemblies. After conversion of the potting technology to closed potting systems with large diaphragm areas (bag concept), reliable electronic assemblies could be produced and operated without failures” (Jülich, ISBN 978-3-89336-922-5, pages 125 to 129, completely freely available in the Internet on the Jülich Open Access Server (JUWEL) at www.fz-juelich.de/zb/juwel).

The company Enitech (Rostock), which deals with the pressure-neutral potting of electronics for the use in the deep sea, shows, for example, an LED spotlight ENI-Light 50 manufactured according to this procedure (datasheet, January 2014, http://www.enitech.de/files/produkte/Datenblatt_LED.pdf).

The indicated bag concept comprises a thin-walled leak-proof silicone layer, the bag into which a component with a liquid potting compound is introduced. In some cases, support and support structures are also encapsulated and provided with fixed covers. Several of these bags can, in turn, be packaged together in a bag and potted together.

The above-mentioned deficiencies of the state of the art are overcome by the inventive method for producing luminaires which are encapsulated in potting compounds, such as, for example, PU (polyurethane), which in particular provides LED luminaires for use in the deep sea, and a device for the production of luminaires potted in potting compound, in particular LED luminaires.

In a further embodiment or variant, the invention also relates to a special UV LED, in particular a UV-C LED, in particular for the use underwater as antifouling means which at least inhibits growth in the environment, for example, of cooling water inlets and/or sensors and thereby positively impact the functionality.

The production of such UV-LEDs with at least one UV-C-LED as a UV-LED segment in which the components of the UV LED segment are encapsulated with one another without inclusion and bubbles and are pressure-neutral, is desired for many reasons, not only for the stability of the mounting of the components, but also for reduction in the number of separate components, simplification of manufacture, improvement of change-out, maintenance and service work, and reliability, and further advantages, attributable, among other things, to modularity

One of the main problems, which occur, for example, in the use of vehicles, machines, components and sensors at sea and in offshore structures, is the growth of the flora and fauna of the sea. This can be countered by the targeted use of UV light, in particular UV-C. Such an application is called an antifouling measure.

The requirements for an inventive cavity-free potted UV LED luminaire with at least one UV-C-LED for the antifouling application, which is used under water, are multi-facetted.

In addition to high energy efficiency, much emphasis is placed on a low-maintenance, compactness, simple design with preferably relatively small geometry and low-cost manufacturing. Furthermore, a redundant, modular network of several such inventive cavity-free potting UV LED luminaires with at least one UV-C LED for anti-fouling use with one another under water is desired for failure safety and performance adjustment.

Particularly when used on components and machines, such as, for example, cooling water inlets, a very flexible adaptability and/or modular, free formability, for example as a ring or part of a circular sector around an inlet, plays a significant role, and is associated with a large light output and a small construction size.

Furthermore, in classic commercially available UV LED “antifouling systems” these are introduced as a non-integrated component into a metal housing and protected by a glass dome.

U.S. Pat. No. 7,341,695, for example, discloses an antifouling apparatus for sensors, with UV light, a control camera and wiper with pressure housing and a dome port, and US 2014 00 78 584 A and WO 2014/014779 A1 disclose UV-C LEDs to prevent fouling on the surface of an optically transparent element or window and UV-C LEDs in a watertight housing with UV-transparent port.

U.S. Pat. No. 4,689,523 describes an optical cleaning system, but not for prevention of growth, for the removal of substances on underwater surfaces with a high energy Xenon or Krypton flash luminaire.

From WO 2013 032 599 A1, a generally held method and apparatus for the anti-biofouling of a surface in a liquid environment by UV light using glass fibers are known.

DE 10 2012 003 284 A1 shows the use of long-wave UV light and visible light from LEDs, which are cast in a cylindrical plastic body made of transparent UV-transparent plastic, such as Makrolon. This device is intended the particular for use with 12 mm glass electrodes of pH and redox sensors due to the relatively small effectiveness of the selected spectrum and material.

The object of the invention is to provide a simple and reliable method for the bubble-free encapsulation of an LED luminaire for use in the deep sea, and thus an LED luminaire, as well as a device for the production of luminaires potted in potting compound, which can be used in particular in a pressure-neutral manner in large sea depths and which consists of a few individual components, the components being held together by the potting compound as a load-bearing element. A main aspect is the use in the deep sea.

Furthermore, a high-power LED light is to be provided for underwater lightning applications and/or as permanent light.

Furthermore, components such as a circuit board or heat sink should be dispensed with, since the inventive LED luminaire allows a sufficient heat dissipation to the environment despite a relatively high output through a complete thin-walled casting without heat sink.

In addition, the invention is based on the object of providing a simple, special method for the production of luminaires cast in potting compound, in a controlled, bubble-free potting of a cavity-free potted UV LED luminaire with at least one UV-C LED for antifouling use under water and a device for producing such luminaires.

These objects or partial objects are solved by the disclosed method and the device as well as the LED according to the independent claims.

The LED luminaire potting method, in particular as a method for a deep-sea LED luminaire, comprises the following steps: configuring an LED luminaire with at least one LED with respective electrically contacting supply line; introducing the configured LED luminaire into a potting mold and fixing at least one lead to the potting mold, wherein components of the LED luminaire which are to be cast do not touch the walls of the potting mold; slewing or panning the potting mold relative to the environment in a gravity system; introducing a potting compound into the potting mold until the components of the LED luminaire to be potted are completely enclosed with the potting compound; optical quality control for the absence of bubbles of the potting compound during curing and, as required, repetitive slewing or panning of the potting mold so that bubbles or gas inclusions located within the potting compound are expressed out of the potting compound.

The luminaire potting method can also be implemented by introducing a configured luminaire to be cast with an optically transparent potting compound into an at least partially optically transparent potting mold, wherein the potting mold is arranged in a vacuum chamber and the luminaire is fixed in the potting mold in a way that the luminaire does not touch the walls of the potting mold; introducing an optically transparent potting compound into the potting mold until the luminaire and any further components of the luminaire to be potted are enclosed; wherein a control of the pressure in the vacuum chamber for influencing the bubbles and/or a control of a panning/tilting device for moving the vacuum chamber and/or the potting mold occurs for expelling or expressing detected gas/air bubbles from the optically transparent encapsulation compound.

The LED luminaire with at least one LED or in a special embodiment also with a UV LED, at least one supply line which electrically contacts the LED and supplies energy, wherein the LED is arranged in a potting compound and, in particular, produced using an LED luminaire potting method according to one of the preceding claims, is characterized in that the at least one LED as well as optional components of the deep-sea LED luminaire and/or common or respective carriers and/or interfaces and/or electronic components are completely enclosed by the potting compound.

The LED luminaire, in particular as a deep-sea LED luminaire, has at least one LED, at least one lead which electrically contacts the LED and which supplies energy, wherein the LED is arranged in a potting compound, wherein the at least one LED and optional components of the deep sea LED luminaire and/or common or respective carriers and/or interfaces and/or electronic components are completely enclosed by the potting compound.

Further optional components of the LED luminaire and/or common or respective carriers and/or reflectors and/or interfaces and/or electronic components can be contacted/arranged/configured before introduction into the potting mold.

The configured LED luminaire is introduced into a potting mold, at least one side surface of the potting mold having a convex geometry.

The introduction of an optically transparent potting compound into the potting mold can take place up until further additional components of the luminaire to be cast are enclosed.

The panning mold is paned about an axis of the concave shaping of the potting compound, whereby a good bubble discharge is forced by rolling the bubbles over the concave bottom.

Control of the panning of the potting mold takes place as a function of the visual quality control with respect to the absence of bubbles in the potting compound.

The curing and panning takes place in a vacuum.

A plurality of LEDs can be arranged in at least one LED array and can be electrically contacted via at least one supply line and/or a component for power supply, the at least one LED array being completely enclosed by the potting compound.

The at least one feed line can have at least one varnish coated wire which is at least partially sheathed with a shrink tube.

The LED luminaire can have at least one reflector, which is at least partially held in the potting compound.

At least one side face of the hardened potting compound of the LED luminaire can have a concave geometry.

The inventive method for the production of luminaires encapsulated in potting compound uses, for example, one or more large-area LEDs or LED arrays, which are mounted on a preferably metallic substrate, for example made of aluminum, or carriers, together with their leads, with optional reflectors potted in a thin potting compound, for example a polyurethane layer, without creating cavities and thus can be used in a watertight manner and under ambient pressure in the deep sea.

Depending on the technical design, interfaces and/or components such as electronic components can be part of the casting. The geometry of the casting can be varied so that different possibilities of attachment and direct integration into a, for example, external, predetermined structure arise. The fasteners can be formed as recesses, tongues, teeth, clamps, holes, threaded holes, threads, clamps or the like.

A minimum number of parts of an LED luminaire is determined by an LED, e.g., high-power LED, SMD-LEDs, lead, e.g., connection wires, and potting compound. Optionally, a carrier for LEDs or LED arrays and/or a reflector can be encapsulated. Boards, housings and covers can be dispensed with.

The at least one LED can in particular be designed as a UV-C LED in order to be used for antifouling applications.

The LED, LEDs or LED arrays are configured for the potting process with or without a carrier and/or, depending on the requirements, with or without reflector or reflectors, and are cast in vacuum with PU only on one connecting wire or several connecting wires of the supply line. Particularly suitable is the use of a varnish coated wire ensheathed with a shrink tube as a connection wire and lead, since this ensures a good adhesion of the PU to the coating of the wire.

The potting compound offers a long-term, mechanically resilient seal on coated wires. At the same time, the coated wire leads serve as fixing points during the potting process and hold the LED and reflector floating in the potting mold.

In order to produce a bubble-free potting, in the inventive method for the production of castings encapsulated in potting compound, the casting is poured into a planar-concave potting mold, in which the base is concave. The potting takes place in a relative vacuum in the realm of the so-called fine vacuum (1 to 10⁻³ hPa). In this case, the detectable bubbles of a gas or of the air are made smaller in proportion to the increase in the relative vacuum, or, larger in the case of a reduction in the relative vacuum.

This effect is utilized to force a good bubble discharge during the potting process by rolling the bubbles over the concave bottom by panning the potting mold about the focal axis of the concave formation of the bottom.

The control of the quality of the bubble-freeness is checked or detected by optical means, preferably or, in particular, by way of a sensor system.

The control of the panning of the potting mold takes place depending on the optical test.

A potting-lamp manufacturing apparatus comprising: a vacuum chamber, an at least partially optically transparent potting mold for receiving a luminaire to be cast with an optically transparent potting compound, a pressure measuring device with a pressure regulator for pressure within the vacuum chamber, an image detector for detecting gas/air bubbles within the at least partially optically transparent potting mold, a tilting/panning device for direct or indirect tilting and panning of the at least partially optically transparent potting mold by tilting and/or panning the at least partially optically transparent potting mold or the vacuum chamber, storage and control unit for controlling the tilting/panning device and/or the pressure within the vacuum chamber.

The image detector is designed as an active sensor, as a camera, and is preferably supported by a light source for backlighting in the case of a fluoroscopy.

The vacuum chamber is at least partially optically transparent so that the image detector can be arranged outside the vacuum chamber.

A supply means is provided for feeding an optically transparent potting compound.

The panning/tilting device is arranged within the vacuum chamber for the exclusive panning of the at least partially optically transparent potting mold.

The at least partially optically transparent potting mold is completely optically transparent.

At least one side of the at least partially optically transparent potting mold has a concave geometry.

The production of planar surfaces in components with low layer strength by potting, even in vacuum, is known to be difficult as is well known in the art. However, in the case of components which are only partially cast, such as, for example, reflectors of luminaires, planar surfaces are often unavoidable.

The inventive method and the inventive device for the production of luminaires cast in potting compound was developed because bubbles in the potting are undesirable, in particular in the case of high pressure differences between luminaire and environment, such as, for example, in the case of deep sea applications, but however low layer thicknesses are required for the heat dissipation of, for example, LEDs or special LEDs.

A further object in the production of such thin-walled castings is to produce as few rejects as possible.

Therefore the process of the potting has to support the quality of the potting process by a quality control. A prerequisite for observability is a transparent vacuum chamber or a vacuum chamber in which optical observations, e.g, through windows, can be carried out. Furthermore, a transparent potting mold and a transparent potting compound is necessary, which allows an optical control.

Auxiliary measures, such as an additional transillumination, e.g, intensive backlighting for an optical sensor, can facilitate the detection of bubbles in the potting compound.

In order to drive out these bubbles trapped on planar surfaces below the potting material, a tilting or panning device as well as a particularly shaped potting mold is used in this device. Furthermore, the bubble size is influenced by a controllable variable negative pressure in the chamber. As a result, automation is also possible for the production of larger quantities. In this case, an image sensor for the optical control is preferably used, which, in particular, carries out an evaluation, storage and, in particular, computer-assisted control of a panning tilt device and tracking of the movement of the bubble or bubbles. If desired, the vacuum can be varied, or can be controlled such that a new cycle of expanding-evacuating can be started.

After expulsion of the bubble (s), the process is terminated and it can be expanded by printing.

All electrical parts are insulated by the potting and there are no cavities which under pressure can lead to structural stresses, rupture of the potting and leakage with subsequent corrosion. The reflector of the LED is cast-in. Within the reflector, the LED is merely coated with a thin PU layer, so that only slight changes in the radiation characteristics under water compared to the application in air result. The thin potting of the LED carrier or substrate ensures adequate cooling within adequately defined tolerances in the underwater operation. Due to the complete encapsulating with PU, the shock resistance and corrosion resistance of the entire unit is further increased. Since no metal surface has any contact with the environment, corrosion and electrochemical processes are prevented.

Due to the absence of pressure bodies, the individual LED luminaires are very light weight and produce only a small amount of downward drift under water. Therefore, the number of pieces used on immersion robots is limited by only by the energy supply and the installation space, but less by their weight.

Since the inventive LED luminaire is usually used for a relatively short time (a few milliseconds) in a flash mode, in which energy-efficient flashes are emitted over shorter intervals, considerably higher currents can flow in this operating mode than in the continuous operation of the LED luminaire. The selection of the power of an LED is limited only by the substrate or carrier surface area as well as a minimum layer thickness of the potting compound with known dissipation of dissipatable heat through the PU mass.

Using the manufacturing process, the inventive LED luminaire can easily be adapted to requirements, for example by adapting the respective LED to the lighting requirements.

By selecting the color temperature of an LED to be installed in the LED luminaire, for example, an adaptation of the light spectrum is achieved as a function of the expected distance of the illumination under water.

A change in the directional characteristics is possible by the choice of suitable reflectors, although conventional reflectors made of plastics can also be used. With a targeted shaping of the geometry of the reflector, the generation of a defined light cone under water is achievable.

The applications for the innovative LED luminaire in the deep sea range to any type of underwater robot, e.g, ROV, AUV, hanging probes or on and in autonomous seabed observatories, and are very versatile.

In addition to being used as a flash array for photography and for stroboscopic time-lapse images of gas emissions at the seabed, the LED luminaire can be used as a working light in continuous operation.

Due to the simple cost-effective manufacture and the low weight of the individual units, the application is very well scalable to very strong lighting systems. At the same time, high energy savings are made possible by stroboscopic control. Unlike xenon flash luminaires LEDs allow high repetition rates, which can be crucial for a complete coverage with photo mapping of the ocean floor and allows high speed flash for video applications.

A further object is to enable the freely selectable geometry of the inventive void-free potted UV-LED luminaire with at least one UVC LED for antifouling use underwater and thus adaptation of antifouling to surfaces in susceptible areas, such as for example free moldable rings or modular segments for cooling water inlets or exposed sensors or sensor domes which do not, or only minimally, engage a surface in the functional design. Through the functional adaptation of the inventive void-free potted UV-LED luminaire having at least one UV-C-LED for the underwater antifouling use, there can easily be provided for example arrays of transducers and sensor networks for greater surface area measurements. The same can also be said for standard LEDs for the purposes of this disclosure, and this refers also to the following additional aspects.

A fixing of the inventive void-free potted UV-LED luminaire with at least one UVC LED for antifouling use under water can simply be made possible by casting magnets, bushings, threaded bushes and/or ball heads in the casting compound of the potting UV-LED luminaire, wherein the bushings, threads, or coupling devices are formable in the potting compound.

The required electronics are in this case cast integrated with the UV-LED having at least one UVC LED. This applies also for a quartz glass window suitable for optical transmission. In the inventive void-free potted UV-LED luminaire conductor boards and heat sinks can be dispensed with, since there is a good heat dissipation through the relatively thin-walled cast body to the surrounding water, even at high power.

The installation of additional LEDs with colored visible light, with indicator and control functions, for example for an active indication for control of the UV-C LED by a user, is also possible. The integrated installation of such LEDs in the visible spectrum, which have the same illumination angle as the UV-C LED, makes possible a simple estimation and adjusting of the light emission cone/effective radius of the entire unit. Here, well known, standardized reflectors can be used and can be cast wholly or partially integrated. Wherein a fixing relative to the light source takes place by the casting.

By this construction of the void-free potted UV-LED luminaire, contact of water with metal surfaces in the casting becomes impossible, and thereby corrosion or electrochemical reaction with water is avoided.

The small number of parts, which consist essentially of the LED, a reflector, a quartz glass window, a supply or internal power supply and the potting material allows for a simple, lightweight, compact, custom-fit to the surrounding construction. Here, for the designer of the innovative void-free potted UV LED luminaire, also concepts such as “form follows function” can be realized.

Optionally, the structure of the inventive void-free potted UV-LED luminaire can also, in addition to the UV-C-LED, include other LEDs that emit in different spectral ranges, including in the visible range, in order to, for example, assume the function of a control LED and/or range of influence LED. Thereby, a setting, fixing and checking during installation is facilitated.

A support for the LED is not absolutely mandatory, but can be used for example as a positioning aid during construction before casting. In general, the components of the inventive void-free potted UV-LED luminaire can be floatingly supported on the lead or lead wires and sealed in vacuum with PU.

To produce a bubble-free casting and thus a void-free potted UV LED luminaire, the casting can have a special design of the casting mold base, which can regulate the bubble dissipation during panning of the casting, which is monitored by an inspection, for example, in backlight.

The leads, which act as a carrier during casting, are made, preferably made of a coated copper wire with a shrin tube in place of normal insulated wire, since PU have good adhesion properties on the coating of the wire. A power supply of the void-free potted UV-LED luminaire is relatively simple and is carried out either externally via the feed line or internally. Since the UV-C LED used as the essential active module in the void-free potted UV-LED luminaire has a relatively low power consumption in the range of a few watts maximum, an external power supply is not mandatory, but rather it may be implemented internally. Thus opting for a pure external power supply of the void-free potted UV LED luminaire via a supply line is rather dependent on whether an easily accessible power supply already exists in the equipment and also whether the active sensors to be protected against fouling require a sustainable continuous energy supply which can feed the void-free potted UV LED luminaire. The void-free potted UV-LED luminaire can, in principle, have its own power supply, such as battery/rechargeable battery instead of or in addition to a supply line. The decision for such a variant of the void-free potted UV LED luminaire depends on the required life span and performance.

At least one quartz glass window may be provided in the radiation path of the UV-C-LED.

Another alternative energy supply for the void-free potted UV LED luminaire and LED version is possible via a wireless energy transfer, such as inductive. In this case, in the void-free potted LED/UV-LED luminaire an inductive interface is used, which corresponds to an external inductive interface, for example, is installed in the object that is to be protected.

Another alternative energy supply for the void-free potted UV LED luminaire and for the LED version is harvesting energy. This can be done for example by producing electricity from temperature differences, or by current flow in the surrounding water, depending on the application.

In another variant the various modules of the void-free potted UV LED luminaire can be manufactured, and installed as individual replaceable filled modules. The molding technology allows a far-reaching form of freedom and adaptability to various geometries. One of the modules can consist for example of the -UV-C-LED with carrier and supply line. The indicator LED and/or scope LED or effective scope control can be installed optionally in a separate module and need not necessarily be a permanent part of the void-free potted UV LED luminaire. The checking of the operating state and the effective radius estimation of the void-free potted UV LED luminaire can also be done by directed measuring devices that are coupled only temporarily to the void-free potted UV LED luminaire.

The electronics of the void-free potted UV LED luminaire provides the required voltage conversion and provides the constant current source for one or more LEDs, as well as a clocked timing.

The inventive method for producing void-free potted UV LED luminaires molded in potting compound, each with at least one UV-C-LED used for example for the antifouling underwater, uses one or more large-area UV-C-LED or LED arrays, which on are mounted on a preferably metallic substrate, for example made of aluminum, or carrier together with their supply lines, suitable optional reflectors are molded in a thin potting compound comprised of polyurethane without creation of cavities is waterproof and therefore can be used under ambient pressure in the deep sea.

Depending on the technical design, interfaces and/or components, such as its electronic components, can be part of the casting. The geometry of the casting can be varied so that different options for fitting and direct integration into for example external, predefined structures arise. The attachment means may be formed as recesses, tabs, teeth, clamps, holes, tapped holes, threads, force fit connections or the like.

The LED, LEDs or LED arrays as UV-C LEDs are configured for the casting process, depending on design, with or without carriers and/or, depending on requirements, with or without a reflector or reflectors and with only one supply line, one lead wire or a plurality of connection wires are cast floating in vacuo with PU. Particularly suitable as connecting wire and lead is the use of a coated wire sheathed with heat shrink tube, since thereby a good adhesion of the PU on the coating of the wire is ensured. The potting compound provides, in the case of coated wires, a long-term mechanical load resisting seal. At the same time coated wire leads serve as fixation points during the casting process and hold the LED and reflector floating in the potting mold.

The process for producing the void-free potted UV-LED luminaire polyurethane (PU) can be carried out comprising the steps of: introducing a configured luminaire to be potted with an optically transparent potting compound made of polyurethane (PU) in an at least partially optically transparent potting mold wherein the potting mold is disposed in a vacuum chamber and the luminaire is fixed in the potting mold such that the light does not touch the walls of the potting mold; introducing an optical-transparent potting material into the potting mold until the luminaire and optional further components of the luminaire to be cast are enclosed; detecting a quantity and quality of a bubble-freeness of the optically-transparent casting compound by an optical sensor or image detector, wherein a regulation of the pressure in the vacuum chamber for influencing the bubbles and/or a regulation of a pan/tilt apparatus for moving the vacuum chamber and/or the potting mold is carried until the expulsion of detected gas/air bubbles from the optically transparent potting compound occurs.

Further, the potted luminaire manufacturing apparatus can be configured with: a vacuum chamber, an at least partially optically transparent potting mold for receiving a luminaire to be potted with an optically-transparent potting compound, a pressure measuring device having a pressure control for the pressure within the vacuum chamber, an image detector for the detection of gas/air bubbles within the at least partially optically transparent potting mold, a pan/tilt apparatus for direct or indirect panning and tilting of the at least partially optically transparent potting mold by panning and/or tilting said at least partly optically transparent potting mold or the vacuum chamber, an evaluation, storage, and control unit for controlling the pan/tilt and/or the pressure within the vacuum chamber.

The inventive method may use, for example, at least one UV-C-LE, optionally other LEDs or LED arrays, which are freely mounted on at least one feed line or on a preferably metallic substrate, for example made of aluminum, or carrier, together with their supply lines, suitable optional reflectors, molded in a potting compound of polyurethane (PU) without creating voids and therefore are waterproof and can be used under ambient pressure in the deep sea.

Further advantages, features and possible applications of the present invention will become apparent from the following description taken in conjunction with the figures.

There is show in:

FIG. 1 an inventive LED luminaire with an LED on a substrate with a reflector in side view and in plan view;

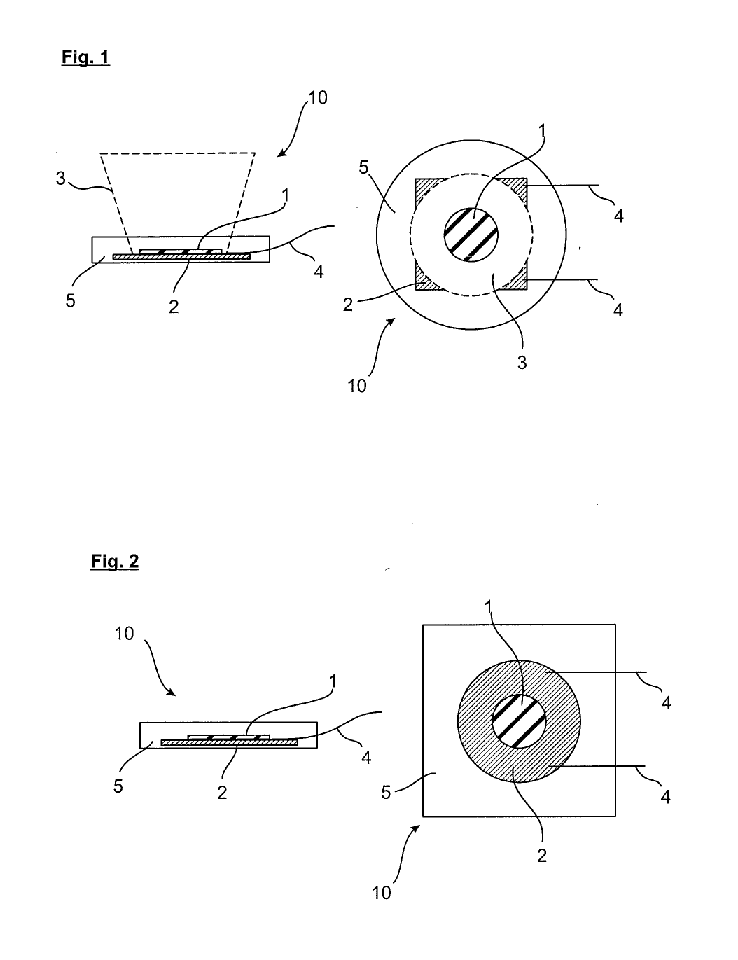

FIG. 2 an inventive LED luminaire with an LED on a support in side view and in plan view;

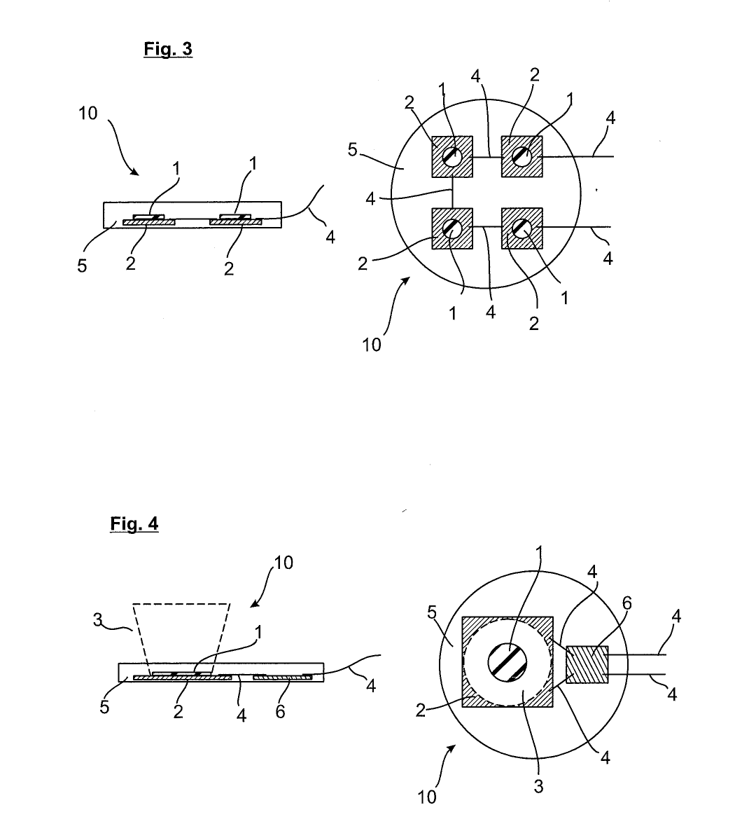

FIG. 3 an inventive LED luminaire having an LED array of LEDs in each case on a support in side view and in plan view;

FIG. 4 an inventive LED luminaire with an LED on a support with an interface or an electronic unit and reflector in side view and in plan view;

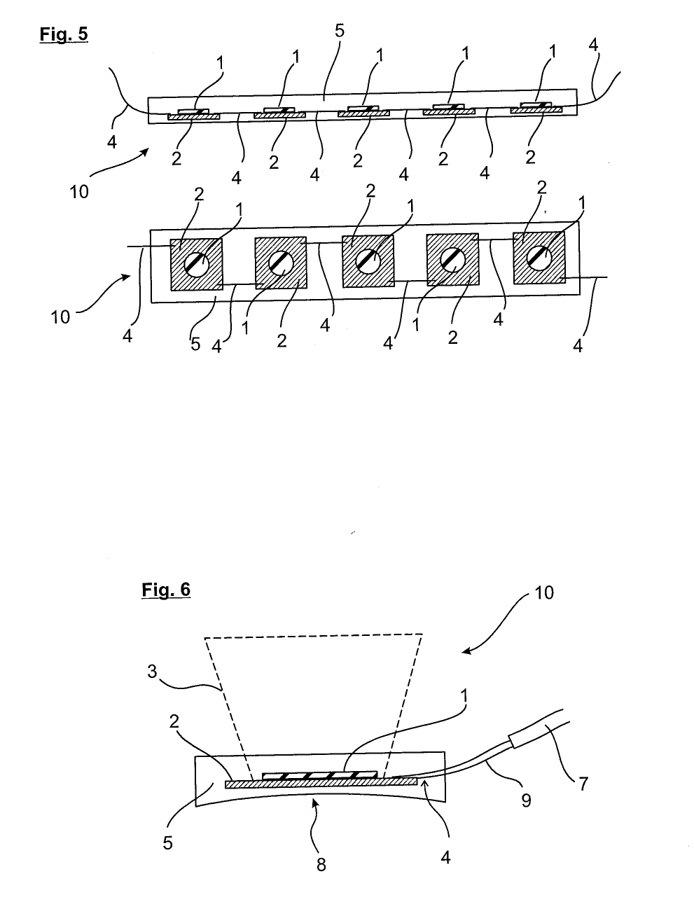

FIG. 5 an inventive LED luminaire having an LED array of LEDs in each case on a support in side view and in plan view in a further variant;

FIG. 6 an inventive LED luminaire with an LED on a substrate with a reflector in side view and plano-concave geometry of the casting compound;

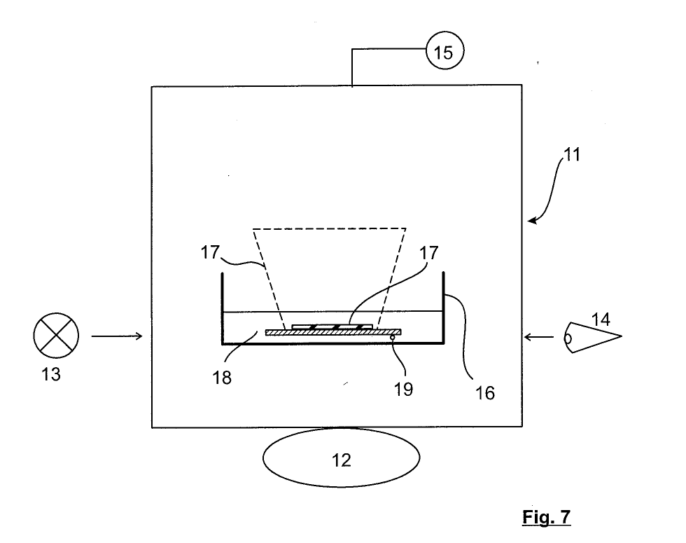

FIG. 7 an apparatus for producing luminaires cast in potting compound;

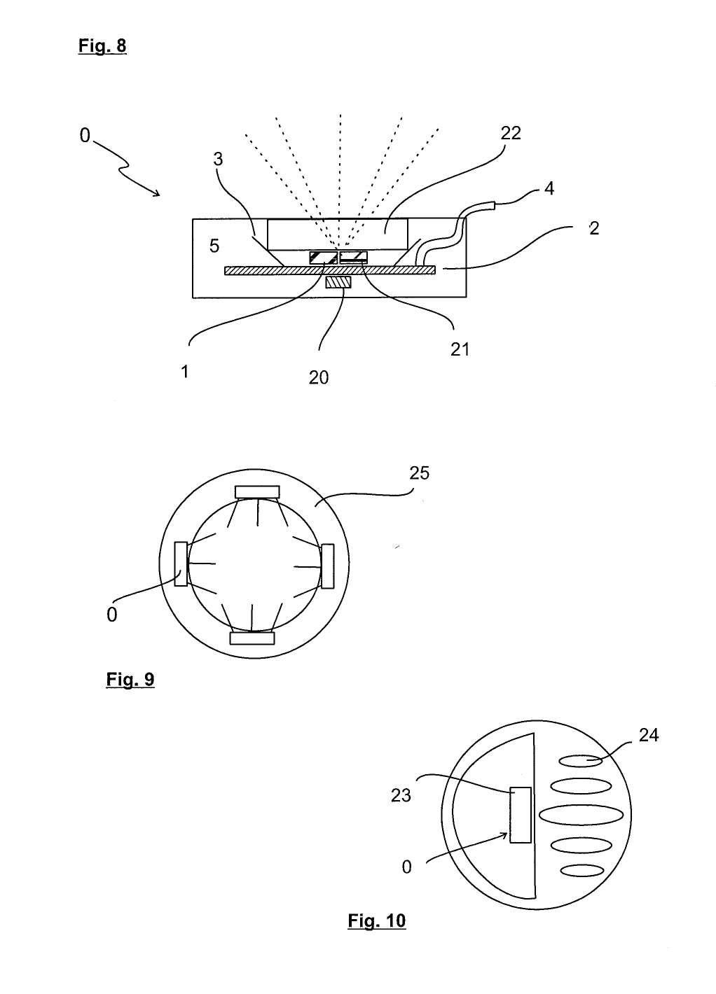

FIG. 8 a first embodiment of an inventive LED luminaire having a UV-LED for the anti-fouling applications;

FIG. 9 a second embodiment of an inventive LED luminaire having a UV-LED for the anti-fouling use; and

FIG. 10 a third embodiment of an inventive LED luminaire having a UV-LED for the anti-fouling applications.

FIG. 1 shows an example of an inventive LED luminaire (10) having a LED (1) on a support (2) with reflector (3) in side view and in plan view. The LED (1) is fixed, for example glued, on a metal support (2), e.g, of aluminum. On the carrier (2) is provided a reflector (3), which surrounds the LED (1) and allows a funnel-shaped focusing of the illumination direction. On the support, a respective supply line (4) is fixed, such as soldered, connected or crimped, which contacts the LED (1) and ensures a supply of electrical energy. The potting compound (5) is formed as a thin circular disc which completely envelopes the LED (1) and the carrier (2). The reflector (3) and the leads (4) are only potted in part.

FIG. 2 shows an example of an inventive LED luminaire (10) having a LED (1) on a support (2) in side view and in plan view. The LED (1) is fixed on a metal support (2). On the support, a respective supply line (4) is fixed, e.g., soldered, to contact the LED (1) and securely supply electrically energy. The potting compound (5) is formed as a thin rectangular plate that completely envelopes the LED (1) and the carrier (2). The leads (4) are potted only in part.

FIG. 3 shows an example of an inventive LED luminaire (10) comprising an LED array of four individual LEDs (1), each on a support (2), in side view and in plan view. The respective LED (1) of the LED array is fixed on a metal support (2). The supports (2) are connected in series by supply lines (4) to each other, the LEDs (1) electrical contact, respectively. The potting compound (5) is formed as a thin circular disc which completely includes the LEDs (1), the intermediate supply lines (4) between the individual LEDs (1) of the LED array and the carrier (2). The other leads (4) are cast only in part.

FIG. 4 shows an example of an inventive LED luminaire (10) having a LED (1) on a support (2) and an interface/component (6) in side view and in plan view. The LED (1) is fixed on a metal support (2). The support (2) is connected in parallel by leads (4) with an interface or an electronic module, which respectively electrically contact the LED (1). The potting compound (5) is formed as a thin circular disc which completely encompasses the LED (1) and the intermediate conductors as supply lines (4) between the LED (1), the interface or the electronic component and the carrier (2). The other leads (4) are cast only in part.

FIG. 5 shows an example of an inventive LED luminaire (10) comprising an LED array of five individual LEDs (1), each on a support (2), in side view and in plan view. The respective LEDs (1) of the LED array are fixed on a metal support (2). The supports (2) are connected to each other in series by supply lines (4), electrical connecting the LEDs (1), respectively. The potting compound (5) is formed as a thin rectangular plate that completely includes the LEDs (1), the intermediate compounds as supply lines (4) between the individual LEDs (1) of the LED array and the carrier (2). The other leads (4) are cast only in part.

FIG. 6 shows an example of an inventive LED luminaire (10) having a LED (1) on a support (2) with reflector (3) in side view. The LED (1) is fixed on a metal support (2). On the carrier (2) is provided a reflector (3), which includes the LED (1) and allows a funnel-shaped focusing of the illumination direction. On the support, a supply line (4) is fixed, comprising a varnish-coated wire (9), which is fixed on the carrier (2), for example, is soldered, and electrically contacts the LED (1) and is enclosed by a shrink sleeve (7). The potting compound (5) is formed as a thin plano-concave disc, which completely encompasses the LED (1) and the carrier (2). The reflector (3) and the leads (4) are cast only in part.

FIG. 7 shows an example of an inventive apparatus for producing cast-in potting compound lights. In an optically transparent vacuum chamber (11), which may also be partially optically transparent or may be provided with a window, there is, in an optically transparent potting mold (16), a luminaire, here for example an LED with a reflector (17) and not shown supply lines (4), kept free. An optically transparent potting compound (18) surrounds the LED with a reflector (17), wherein the reflector protrudes from the optically transparent potting compound (18). By a pressure measuring device (5), the control of the pressure can be monitored, by which the air bubble size of an air bubble (9) in the optically transparent potting compound (18) can be influenced. The air bubble (9) is detected by an image detector (14) by the optically transparent vacuum chamber (11), which qualitatively and quantitatively determines, through the optically transparent potting mold (16) into the optically transparent potting compound (18), a status of bubbles (9) and forwards this to a not shown evaluation, storage and control unit. By this control unit a pan/tilt apparatus (12) is controlled in its movement, which moves the optically transparent vacuum chamber (11) and the optically transparent potting mold (16) such that the air bubbles (9) are expelled from the optically transparent potting compound (18). The image detector can be to be actively operated, and also be supported by a suitable light source for backlight (13).

In FIG. 8 a first embodiment of an inventive LED luminaire with a UV LED is shown for the anti-fouling applications.

Reference is made to the previously illustrated embodiments in general. Here, a UV-LED 1 is supported on a carrier 2. In addition, a control LED 20 and a sphere-of-influence LED 21 is provided on this carrier 2 to detect the area of influence or to control the function. Further, a quartz glass window 22 is additionally arranged. This unit is referred to as LED light segment 0.

FIG. 9 shows a second embodiment of an inventive LED luminaire having a UV-LED for the anti-fouling applications.

There is shown a pipe 25, in which four UV-LED luminaires 0 keep the pipe free, whereby an antifouling is realized.

FIG. 10 illustrates a third embodiment of an inventive LED luminaire having a UV-LED for anti-fouling applications.

Here, a cooling water inlet 24 is shown, wherein a UV-LED luminaire segment 0 keeps the inlets free. The LED luminaire segment 0 has integrated electronics with constant current supply and clocking 23.

### LIST OF REFERENCE NUMBERS

0 LED luminaire segment
1 LED, UV LED, UV-LED-C
2 carrier
3 reflector
4 lead
5 potting compound
6 interface or electronic component
7 shrink tubing
8 concave base
9 coated wire
10 LED luminaire
11 optically transparent vacuum chamber
12 pan/tilt device
13 light source for backlighting
14 image detector
15 pressure gauge
16 optically transparent potting mold
17 LED with reflector
18 optically transparent potting compound
19 bubble
20 control LED
21 sphere-of-influence LED
22 quartz glass window
23 electronics with constant current supply and/or clock
24 cooling water intake
25 pipe

1. LED-luminaire-potting-method comprising the steps:
introducing a luminaire configured to be potted with an optically transparent potting compound in an at least partially optically transparent potting mold (16), wherein the potting mold (16) is arranged in a vacuum chamber (11) and the luminaire is positioned in the potting mold (16) in such a way that the luminaire does not touch the walls of the potting mold;
introducing an optically transparent potting compound (18) into the potting mold (16) until at least the luminaire is enclosed;
detecting the quantity and quality of a bubble-freeness of the optically transparent potting compound (18) via an optical sensor or photo detector (14),
wherein there occurs
a regulation of the pressure in the vacuum chamber (11) for influencing the bubbles
and/or
a control of a pan/tilt apparatus (12) for movement of the vacuum chamber (11) and/or the potting mold (16) for expulsion of detected gas/air bubbles (19) from the optically transparent potting compound (18).

2. LED-luminaire-potting-method according to claim 1,
characterized in that
the introduction of an optically transparent potting compound (18) into the potting mold (16) continues until further additional components to be of the luminaire to be potted are enclosed.

3. LED-luminaire-potting-method according to claim 1 or 2,
characterized in that
other optional components of the LED luminaire and/or a common or respective support and/or reflector(s) and/or interfaces and/or electronic components are contacted/arranged/configured prior to introduction into the potting mold.

4. LED-luminaire-potting-method according to claim 1, 2 or 3,
characterized in that
the introduction of the configured LED light into a potting mold takes place, wherein at least one side surface of the potting mold has a convex geometry and that a panning of the potting mold about a focal axis of the concave shape of the casting compound occurs, whereby a good bubble expulsion is forced by rolling the bubbles over the concave bottom.

5. LED luminaire having at least one LED, at least one supply line electrical contacting the LED and supplying it with power, wherein the LED is disposed in a potting compound and has been prepared in particular with an LED luminaire-potting method according to any one of the preceding claims,
characterized in that
the at least one LED as well as optional components of the deep-sea LED light and/or common or respective carrier and/or interfaces and/or electronic components are completely enclosed by the potting compound.

6. LED luminaire according to the preceding claim,
characterized in that
a plurality of LEDs are arranged in at least one LED array and electrically contacted and can be supplied with energy via at least one supply line and/or a component for energy supply, wherein the at least one LED-array completely is enclosed by the potting compound.

7. LED luminaire according to one of the two preceding claims,
characterized in that
the at least one input lead having at least one coated wire is at least partially encased with a shrink tube
and/or
the LED luminaire comprises at least one reflector, which is in each case at least partially retained in the potting compound
and or
at least one side surface of the potting compound has a concave geometry.

8. LED luminaire according to one of the three preceding claims,
characterized in that
the LED is at least one UV-C-LED.

9. LED luminaire according to one of the four preceding claims,
characterized in that
a quartz glass window is provided in at least the emission direction of the LED-UV-C.

10. LED luminaire according to one of the five preceding claims,
characterized in that
the at least one UVC LED is functionally coupled with at least one area-of-influence LED and/or a control LED.

11. LED-potted-luminaire manufacturing apparatus comprising:
a vacuum chamber (11),
an at least partially optically transparent potting mold (16) for receiving a luminaire to be potted in an optically-transparent potting compound,
a pressure measuring device (15) with a pressure controller for the pressure within the vacuum chamber (11),
an image detector (14) for the detection of gas/air bubbles within the at least partially optically transparent potting mold (16),
a pan/tilt apparatus (12) for direct or indirect panning and tilting of the at least partially optically transparent potting mold (16) by panning and/or tilting said at least partly optically transparent potting mold (16) or the vacuum chamber (11),
an evaluation, storage, and control unit for controlling the pan/tilting device (12) and/or the pressure within the vacuum chamber (11).

12. LED-potted-luminaire manufacturing apparatus according to the preceding claim,
characterized in that
the image detector is an active sensor, a camera, preferably supportable by a light source for back light (13) for fluoroscopy.

13. LED-potted-luminaire manufacturing apparatus according to one of the two preceding claims,
characterized in that
the vacuum chamber (11) is formed at least partially optically transparent so that the image detector can be arranged outside the vacuum chamber (11).

14. Potted luminaire manufacturing apparatus according to any one of the three preceding claims,
characterized in that
the pan/tilt device (12) is disposed within the vacuum chamber for exclusive panning of the at least partially optically transparent potting mold (16).

15. Potted luminaire manufacturing apparatus according to any one of the four preceding claims,
characterized in that
the at least partially optically transparent potting mold (16) is completely formed optically-transparent
and/or
at least one side of the at least partially optically transparent potting mold (16) has a concave geometry.
